(19) United States
(12) Patent Application Publication
(10) Pub. No.: US 2012/0293957 A1
(43) Pub. Date: Nov. 22, 2012

(54) HEAT DISSIPATING SYSTEM FOR COMPUTER

(75) Inventors: Jin-Biao JI, Wuhan City (CN); Zhi-Jiang YAO, Wuhan City (CN); Li-Fu XU, Wuhan City (CN)

(73) Assignees: HON HAI PRECISION INDUSTRY CO., LTD., Tu-Cheng (TW); HONG FU JIN PRECISION INDUSTRY (WuHan) CO., LTD., Wuhan City (CN)

(21) Appl. No.: 13/296,528

(22) Filed: Nov. 15, 2011

(30) Foreign Application Priority Data
May 16, 2011 (CN) 201110124847.7

(51) Int. Cl. H05K 7/20

(52) U.S. Cl. 361/692

(57) ABSTRACT

A heat dissipating system includes an enclosure, which includes a rear plate and a side plate. A heat sink is mounted on the side plate. A power supply unit is mounted on the rear plate. A first fan is mounted in an inner room of the power supply unit. The power supply unit includes a bottom wall which defines a plurality of first vent holes and a rear wall which defines a plurality of second vent holes. The first fan is aligned to the plurality of second vent holes. The bottom wall is located above the heat sink. The first fan is adapted to rotate to drive air flowing in the power supply unit via the plurality of first vent holes from the heat sink, and following out of the power supply unit via the plurality of second vent holes.

### BACKGROUND

1. Technical Field

The present disclosure relates to heat dissipating systems for computers, and more particularly to a heat dissipating system which dissipates heat in a high efficiency.

2. Description of Related Art

Presently, various electrical devices, especially the desktop computer, are crowded with different electrical components and peripheral devices, such as the central processing units (CPUs), the interface cards, the data storage devices, and the power supplies. These electrical components and peripheral devices generate heat during operation, causing the inner temperature of the desktop computer enclosure to become very high. Therefore, more heat dissipation devices are installed inside the computer chassis to remove the excessive heat generated by the electrical components and peripheral devices. However, too much heat dissipation devices takes up too much inner room of the computer.

Therefore, there is room for improvement within the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded and isometric view of an embodiment of a heat dissipating system for a computer.

FIG. 2 is an isometric view of a power supply unit of the heat dissipating system of FIG. 1.

FIG. 3 is another isometric view of the power supply unit of FIG. 2.

FIG. 4 is an assembled view of the heat dissipating system of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

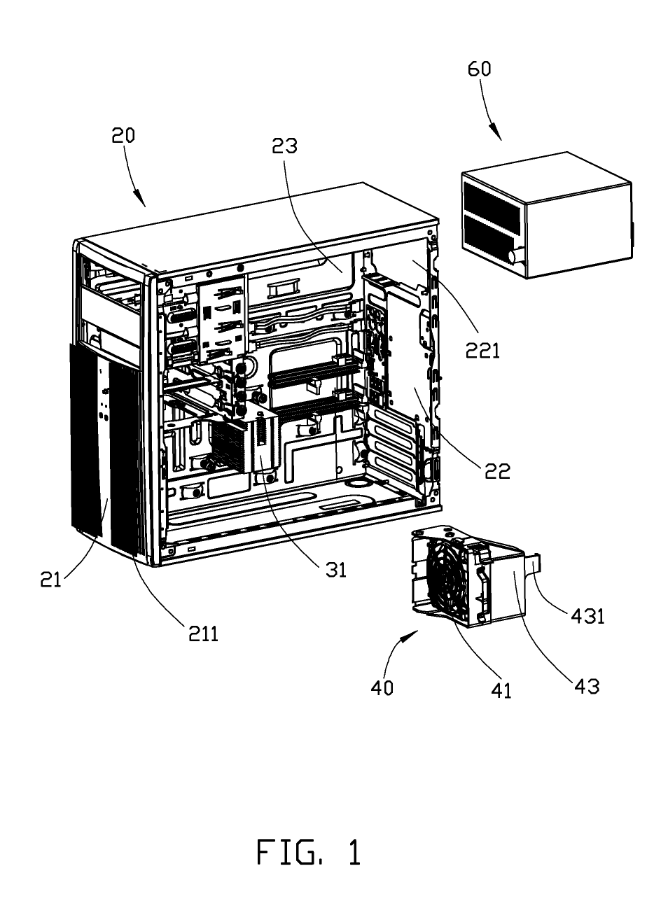

Referring to FIG. 1, a heat dissipating system for a computer in accordance with an embodiment includes an enclosure 20 and a plurality of components which is mounted in the enclosure 20. The plurality of components includes a heat sink 31 and a power supply unit 60.

The enclosure 20 includes a front plate 21, a rear plate 22, and a side plate 23. The front plate 21 is parallel to the rear plate 22. The side plate 23 is perpendicularly connected between the front plate 21 and the rear plate 22. The lower portion of the front plate 21 defines a plurality of vent gaps 211. The higher portion of the rear plate 22 defines a rectangular opening 221.

The heat sink 31 is mounted on the side plate 23. The heat sink 31 is located nearer to the front plate 21 than the rear plate 22. The heat sink 31 is aligned to the plurality of vent gaps 211.

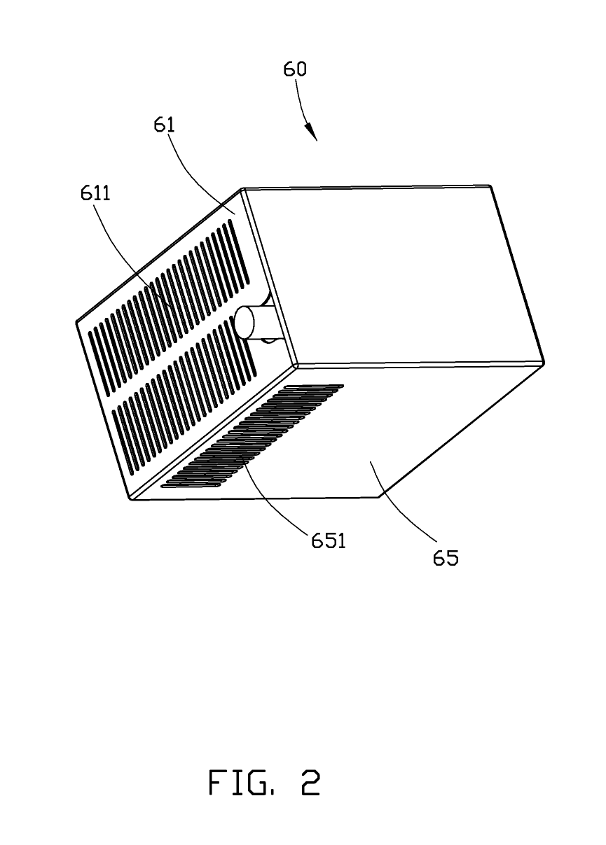

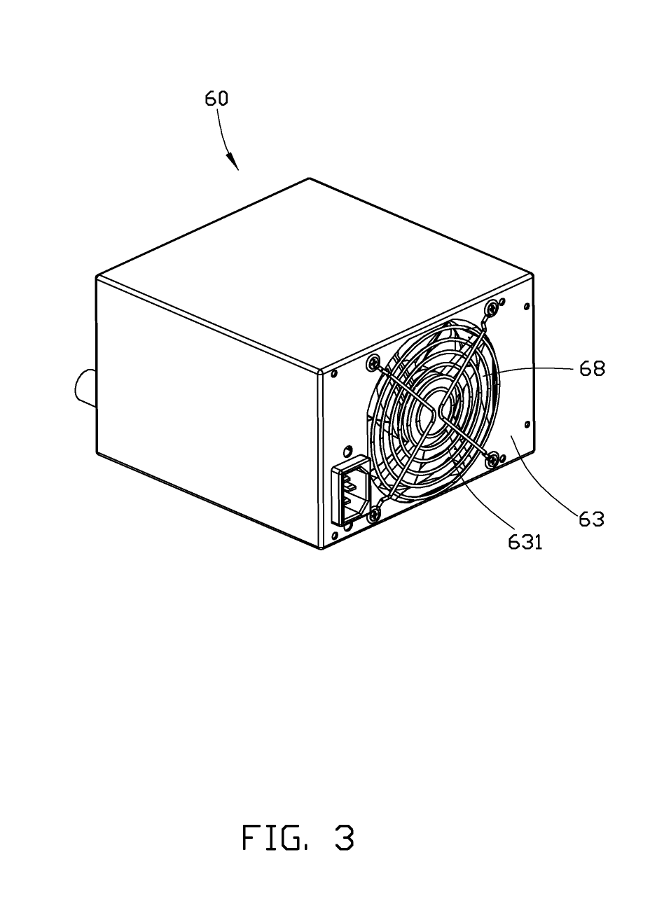

Referring to FIGS. 1 to 3, the power supply unit 60 can be a square. A cross-section of the power supply unit 60 is equal to the opening 221 of the rear plate 22. In the exemplary embodiment, the opening 221 is rectangular thus the cross-section of the power supply unit 60 is also rectangular. The power supply unit 60 can be inserted into or removed out of the enclosure 20 via the opening 221. The power supply unit 60 includes a front wall 61, a rear wall 63, and a bottom wall 65. The front wall 61 is parallel to the rear wall 63. The bottom wall 65 is perpendicular to the front wall 61 and connected between the front wall 61 and the rear wall 63. A portion of the bottom wall 65, which is adjacent to the front wall 61, defines a plurality of first vent holes 651. The rear wall 63 defines a plurality of second vent holes 631. The front wall 61 defines a plurality of third vent holes 611. A first fan 68 is mounted in the power supply unit 60. The first fan 68 is aligned to the plurality of second vent holes 631.

A fan module 40 can be mounted on the heat sink 31. The fan module 40 includes a second fan 41 and an air duct 43. The air duct 43 includes a first side and a second side intercommunication with the first side. The second fan 41 is mounted on the first side of the air duct 43. A plurality of clasps 431 is formed on the second side of the air duct 43.

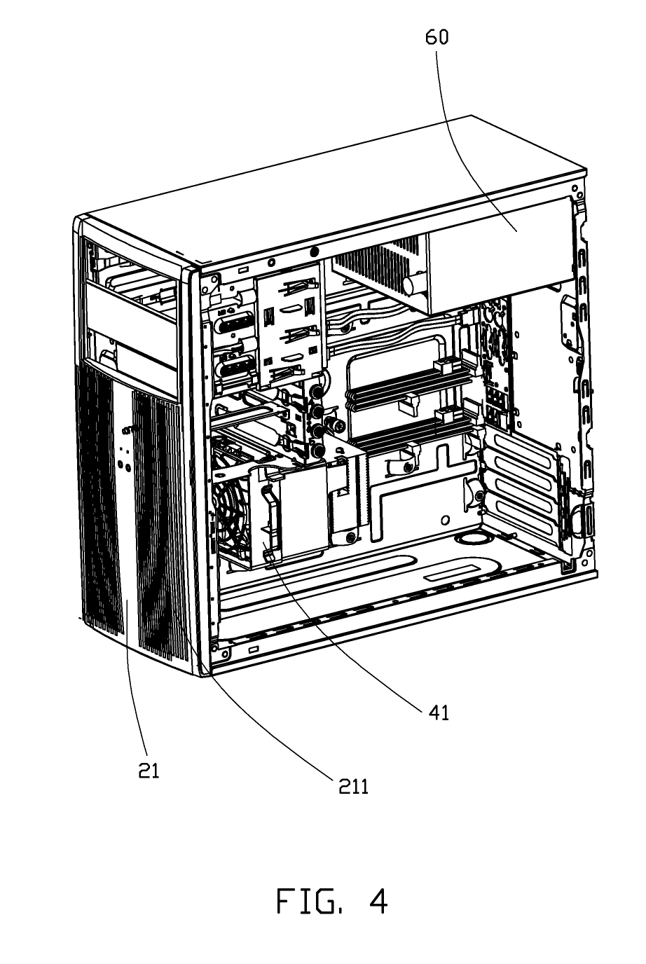

Referring to FIGS. 1 to 4, in assembly, the power supply unit 60 is moved in the enclosure 20 via the opening 221. The rear wall 63 of the power supply unit 60 and the rear plate 22 are located on the same plane. At this position, the bottom wall 65 of the power supply unit 60 is located above the heat sink 31. Then, the second side of the air duct 43 is aligned to the heat sink 31. The clasps 431 engage on the heat sink 31 to mount the fan module 40 on the heat sink 31. The fan module 40 is located between the heat sink 31 and the front plate 21. The second fan 41 faces to the vent gaps 211 of the front plate 21.

When the heat dissipating system is in use, the second fan 41 rotates to drive air flowing in the enclosure 20 via the vent gaps 211. Air then flows through the air duct 43 and the heat sink 31 to bring heat from the heat sink 31. The first fan 68 rotates to drive air flowing in the power supply unit 60 from the heat sink 31 via the first vent holes 651 and the third vent holes 611. Air brings heat from the power supply unit 60. At last, air is dissipated from the power supply unit 60 via the second vent holes 631 by the first fan 68.

In the heat dissipating system, because the first vent holes 651 is defined on the bottom wall 65 of the power supply unit 60 and the bottom wall 65 is located above the heat sink 31, air can flow in the power supply unit 60 from the heat sink 31 to dissipate heat of the heat sink 31 and the power supply unit 60.

It is to be understood, however, that even though numerous characteristics and advantages of the embodiments have been set forth in the foregoing description, together with details of the structure and functions of the embodiments, the disclosure is illustrative only, and changes may be made in detail, especially in the matters of shape, size, and arrangement of parts within the principles of the invention to the full extent indicated by the broad general meaning of the terms in which the appended claims are expressed.

What is claimed is:

1. A heat dissipating system, comprising:
an enclosure comprising a rear plate and a side plate;
a heat sink mounted on the side plate; and
a power supply unit mounted on the rear plate, a first fan mounted in an inner room of the power supply unit, the power supply unit comprising a bottom wall, which defines a plurality of first vent holes, and a rear wall, which defines a plurality of second vent holes, the first fan aligned to the plurality of second vent holes, the bottom wall located above the heat sink, wherein the first fan is adapted to drive air to flow in the power supply unit from the heat sink via the plurality of first vent holes and to drive the air to follow out of the power supply unit via the plurality of second vent holes.

2. The heat dissipating system of claim 1, wherein the rear wall is perpendicular to the bottom wall, and the rear plate is perpendicular to the side plate.

3. The heat dissipating system of claim 1, wherein the enclosure comprises a front plate which is parallel to the rear plate, the side plate is perpendicular to the front plate, and the front plate defines a plurality of vent gaps which is aligned to the heat sink.

4. The heat dissipating system of claim 3, comprising a fan module located between the heat sink and the front plate, and the fan module comprising a second fan which is aligned to the plurality of vent gaps.

5. The heat dissipating system of claim 4, wherein the fan module comprises an air duct which comprises a first side and a second side intercommunication with the first side, the second fan is mounted on the first side of the air duct, a plurality of clasps is positioned on the second side of the air duct, and the plurality of clasps is engaged on the heat sink.

6. The heat dissipating system of claim 1, wherein the rear plate defines an opening, and the power supply unit is adapted to be moved into the enclosure via the opening.

7. The heat dissipating system of claim 6, wherein the rear wall is placed in the opening, and the rear wall and the rear plate are located on a same plane.

8. The heat dissipating system of claim 1, wherein the power supply unit further comprises a front wall which is parallel to the rear wall, the bottom wall is perpendicularly connected between the front wall and the rear wall, and the front wall defines a plurality of third vent holes.

9. An enclosure assembly, comprising:
a rear plate defining an opening, a power supply unit mounted in the rear plate and aligned to the opening, the power supply unit comprising a rear wall which is located in the opening, the rear wall and the rear plate located in a same plate, the power supply unit further comprising a bottom wall, the bottom wall defining a plurality of first vent holes, the rear wall defining a plurality of second vent holes, a first fan located in the power supply unit and aligned to the plurality of second vent holes;
a side plate, a heat sink mounted on the side plate, and the heat sink located below the bottom wall;
wherein the first fan is adapted to rotate to form an air channel, and the heat sink, the plurality of first vent holes, the first fan, and the plurality of second vent holes are located in the air channel.

10. The enclosure assembly of claim 9, wherein the rear wall is perpendicular to the bottom wall, and the rear plate is perpendicular to the side plate.

11. The enclosure assembly of claim 9, wherein the enclosure assembly further comprises a front plate which is parallel to the rear plate, the side plate is perpendicular to the front plate, and the front plate defines a plurality of vent gaps which is aligned to the heat sink.

12. The enclosure assembly of claim 11, wherein a fan module is located between the heat sink and the front plate, and the fan module comprises a second fan which is aligned to the plurality of vent gaps.

13. The enclosure assembly of claim 12, wherein the fan module comprises an air duct which comprises a first side and a second side intercommunication with the first side, the second fan is mounted on the first side of the air duct, a plurality of clasps is formed on the second side of the air duct, and the plurality of clasps is engaged on the heat sink.

14. The enclosure assembly of claim 9, wherein the power supply unit comprises a front wall which is parallel to the rear wall, the bottom wall is perpendicularly connected between the front wall and the rear wall, and the front wall defines a plurality of third vent holes.
